(19) United States
(12) Patent Application Publication
(10) Pub. No.: US 2026/0245638 A1
(43) Pub. Date: Aug. 20, 2026

(54) SYSTEM AND METHOD FOR PROGRESSIVE READ AND SOFT DECODING FOR MEMORY DEVICES

(71) Applicant: SK hynix Inc., Gyeonggi-do (KR)

(72) Inventors: Fan ZHANG, San Jose, CA (US); Pengfei HUANG, San Jose, CA (US); Haobo WANG, San Jose, CA (US)

(21) Appl. No.: 19/056,735

(22) Filed: Feb. 19, 2025

(51) Int. Cl. G11C 16/34; G11C 29/52

(52) U.S. Cl. CPC G11C 16/3418; G11C 16/3404; G11C 29/52

(57) ABSTRACT

A memory system includes a memory device including one or more memory cells for storing data, and a controller coupled to the memory device. The controller is configured to: perform at least first and second read operations on the data of the memory cells using first and second read voltages, respectively, in response to a read command, to generate first and second read values; determine a best read value among the first and second read values; generate at least one log-likelihood ratio (LLR) value based on the first and second read values; and perform a soft decoding based on the best read value and the LLR values

[symbol]

### BACKGROUND

### 1. Field

Embodiments of the present disclosure relate to a scheme for a read operation of a memory system.

### 2. Description of the Related Art

The computer environment paradigm has shifted to ubiquitous computing systems that can be used anytime and anywhere. As a result, the use of portable electronic devices such as mobile phones, digital cameras, and notebook computers has rapidly increased. These portable electronic devices generally use a memory system having memory device(s), that is, data storage device(s). The data storage device is used as a main memory device or an auxiliary memory device of the portable electronic devices. Data storage devices using memory devices provide excellent stability, durability, high information access speed, and low power consumption, since they have no moving parts. Examples of data storage devices having such advantages include universal serial bus (USB) memory devices, memory cards having various interfaces, and solid state drives (SSD).

Memory systems can perform operations such as read and decoding operations on data stored therein. In this context, embodiments of the present invention arise.

### SUMMARY

Aspects of the present invention include a system and a method for providing progressive read and soft decoding operations in order to improve quality of service (QoS), performance and reliability of memory systems.

In one aspect, there is provided a memory system comprising a memory device including one or more memory cells for storing data, and a controller coupled to the memory device. The controller is configured to: perform at least first and second read operations on the data of the memory cells using first and second read voltages, respectively, in response to a read command, to generate first and second read values; determine a best read value among the first and second read values; generate at least one log-likelihood ratio (LLR) value based on the first and second read values; and perform a soft decoding based on the best read value and the LLR values.

In another aspect, there is provided a method for operating a memory system including a memory device including one or more memory cells for storing data, and a controller coupled to the memory device. The method includes performing at least first and second read operations on the data of the memory cells using first and second read voltages, respectively, in response to a read command, to generate first and second read values; determining a best read value among the first and second read values; generating at least one log-likelihood ratio (LLR) value based on the first and second read values; and performing a soft decoding based on the best read value and the LLR values.

Additional aspects of the present invention will become apparent from the following description.

### BRIEF DESCRIPTION OF THE DRAWINGS

FIG. 1 is a block diagram illustrating a data processing system.

FIG. 2 is a block diagram illustrating a memory system.

FIG. 3 is a circuit diagram illustrating a memory block of a memory device.

FIG. 4 is a diagram illustrating distributions of states for different types of cells of a memory device.

FIG. 5A is a diagram illustrating an example of Gray coding for a multi-level cell (MLC).

FIG. 5B is a diagram illustrating state distributions for pages of a multi-level cell (MLC).

FIG. 6A is a diagram illustrating one example of Gray coding for a triple-level cell (TLC).

FIG. 6B is a diagram illustrating state distributions for pages of a triple-level cell (TLC).

FIG. 7 is a diagram illustrating one example of Gray coding and state distributions for pages of a quadruple-level cell (QLC).

FIG. 8 is a diagram illustrating a flow of an error recovery algorithm in a memory system.

FIG. 9 is a diagram illustrating a memory system in accordance with one embodiment of the present invention.

FIG. 10 is a diagram illustrating a format of a codeword to be stored in a storage system in accordance with embodiments of the present invention.

FIG. 11 is a flowchart illustrating a progressive read and decoding operation in accordance with embodiments of the present invention.

FIG. 12 is a diagram illustrating performance of a progressive read and decoding operation in accordance with embodiments of the present invention.

FIG. 13 is a flowchart illustrating an operation according to one embodiment of the invention.

### DETAILED DESCRIPTION

Various embodiments of the present invention are described below in more detail with reference to the accompanying drawings. The present invention may, however, be embodied in different forms and thus should not be construed as limited to the embodiments set forth herein. Rather, these embodiments are provided so that this disclosure conveys the scope of the present invention to those skilled in the art. Moreover, reference herein to “an embodiment,” “another embodiment,” or the like is not necessarily to only one embodiment, and different references to any such phrase are not necessarily to the same embodiment(s). The term “embodiments” as used herein does not necessarily refer to all embodiments. Throughout the disclosure, like reference numerals refer to like parts in the figures and embodiments of the present invention.

The present invention can be implemented in numerous ways, for example including as a process; an apparatus; a system; a computer program product embodied on a computer-readable storage medium; and/or a processor, such as a processor suitable for executing instructions stored on and/or provided by a memory coupled to the processor. In this specification, these implementations, or any other form that the present invention may take, may be referred to as techniques. In general, the order of the operations of disclosed processes may be altered within the scope of the present invention. Unless stated otherwise, a component such as a processor or a memory described as being suitable for performing a task may be implemented as a general device or circuit component that is configured or otherwise programmed to perform the task at a given time or as a specific device or as a circuit component that is manufactured or pre-configured or pre-programmed to perform the task. As used herein, the term ‘processor’ or the like refers to one or more devices, circuits, and/or processing cores suitable for processing data, such as computer program instructions.

The methods, processes, and/or operations described herein may be performed by code or instructions to be executed for example by a computer, processor, controller, or other signal processing device. The computer, processor, controller, or other signal processing device may be those described herein or one in addition to the elements described herein. Because the algorithms that form the basis of the methods (or operations of the computer, processor, controller, or other signal processing device) are described herein, the code or instructions for implementing the operations of the method embodiments may transform the computer, processor, controller, or other signal processing device into a special-purpose processor for performing any one of the methods herein.

If implemented at least partially in software, the controllers, processors, devices, modules, units, multiplexers, generators, logic, interfaces, decoders, drivers, generators and other signal generating and signal processing features may include, for example, a memory or other storage device for storing code or instructions to be executed, for example, by a computer, processor, microprocessor, controller, or other signal processing device.

A detailed description of various embodiments of the present invention is provided below along with accompanying figures that illustrate aspects of the present invention. The present invention is described in connection with such embodiments, but the present invention is not limited to any specific embodiment. The present invention encompasses numerous alternatives, modifications and equivalents. Numerous specific details are set forth in the following description in order to provide a thorough understanding of the present invention. These details are provided for the purpose of example; the present invention may be practiced without some or all of these specific details. For clarity, technical material that is known in technical fields related to the present invention has not been described in detail so that the invention is not unnecessarily obscured.

Semiconductor memory devices may be volatile or nonvolatile. The volatile semiconductor memory devices perform read and write operations at high speeds, while contents stored therein may be lost at power-off. The nonvolatile semiconductor memory devices may retain contents stored therein even at power-off. The nonvolatile semiconductor memory devices may be used to store contents, which must be retained regardless of whether they are powered.

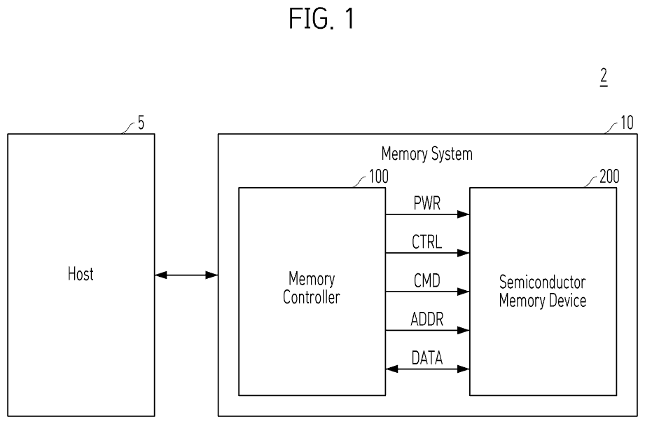

FIG. 1 is a block diagram illustrating a data processing system 2 in accordance with one embodiment of the present invention.

Referring FIG. 1, the data processing system 2 may include a host device 5 and a memory system 10. The memory system 10 may receive a request from the host device 5 and operate in response to the received request. For example, the memory system 10 may store data to be accessed by the host device 5.

The host device 5 may be implemented with any of various types of electronic devices. In various embodiments, the host device 5 may be an electronic device such as for example a desktop computer, a workstation, a three-dimensional (3D) television, a smart television, a digital audio recorder, a digital audio player, a digital picture recorder, a digital picture player, and/or a digital video recorder and a digital video player. In various embodiments, the host device 5 may be a portable electronic device such as for example a mobile phone, a smart phone, an e-book, an MP3 player, a portable multimedia player (PMP), and/or a portable game player.

The memory system 10 may be implemented with any of various types of storage devices such as a solid state drive (SSD) and a memory card. In various embodiments, the memory system 10 may be provided as one of various components in an electronic device such as for example a computer, an ultra-mobile personal computer (PC) (UMPC), a workstation, a net-book computer, a personal digital assistant (PDA), a portable computer, a web tablet PC, a wireless phone, a mobile phone, a smart phone, an e-book reader, a portable multimedia player (PMP), a portable game device, a navigation device, a black box, a digital camera, a digital multimedia broadcasting (DMB) player, a 3-dimensional television, a smart television, a digital audio recorder, a digital audio player, a digital picture recorder, a digital picture player, a digital video recorder, a digital video player, a storage device of a data center, a device capable of receiving and transmitting information in a wireless environment, a radio-frequency identification (RFID) device, as well as one of various electronic devices of a home network, one of various electronic devices of a computer network, one of electronic devices of a telematics network, or one of various components of a computing system.

The memory system 10 may include a memory controller 100 and a semiconductor memory device 200. The memory controller 100 may control overall operations of the semiconductor memory device 200 including those of bit error rate reporting as detailed below.

The semiconductor memory device 200 may perform one or more erase, program, and read operations under the control of the memory controller 100. The semiconductor memory device 200 may receive through input/output lines a command CMD, an address ADDR and data DATA. The semiconductor memory device 200 may receive power PWR through a power line and a control signal CTRL through a control line. The control signal CTRL may include for example a command latch enable signal, an address latch enable signal, a chip enable signal, a write enable signal, a read enable signal, as well as other operational signals depending on design and configuration of the memory system 10.

The memory controller 100 and the semiconductor memory device 200 may be integrated in a single semiconductor device such as a solid state drive (SSD). The SSD may include a storage device for storing data therein.

The memory controller 100 and the semiconductor memory device 200 may be integrated in a single semiconductor device such as a memory card. For example, the memory controller 100 and the semiconductor memory device 200 may be integrated to configure a personal computer (PC) card of personal computer memory card international association (PCMCIA), a compact flash (CF) card, a smart media (SM) card, a memory stick, a multimedia card (MMC), a reduced-size multimedia card (RS-MMC), a micro-size version of MMC (MMCmicro), a secure digital (SD) card, a mini secure digital (miniSD) card, a micro secure digital (microSD) card, a secure digital high capacity (SDHC), and/or a universal flash storage (UFS).

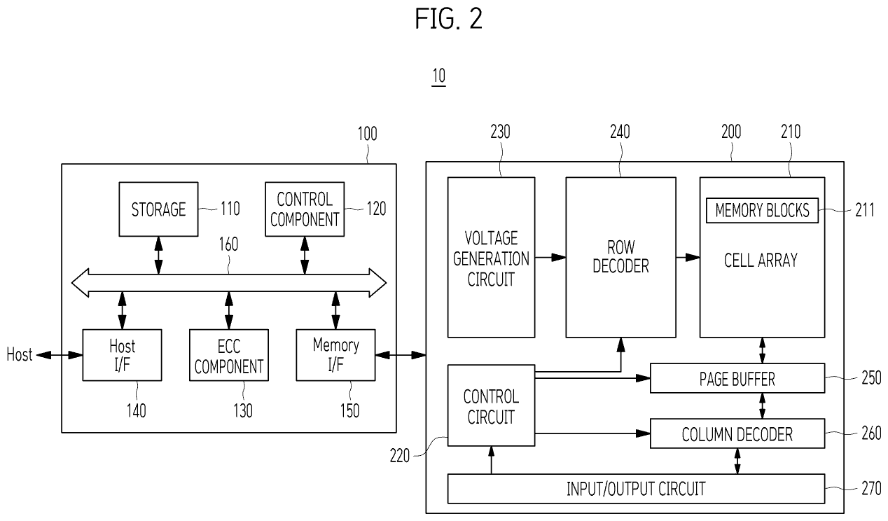

FIG. 2 is a block diagram illustrating a memory system in accordance with one embodiment of the present invention. For example, the memory system of FIG. 2 may depict the memory system 10 shown in FIG. 1.

Referring to FIG. 2, the memory system 10 may include a memory controller 100 and a semiconductor memory device 200. The memory system 10 may operate in response to a request from a host device (e.g., a request from host device 5 of FIG. 1), and in particular, store data to be accessed by the host device.

The memory device 200 may store data to be accessed by the host device.

The memory device 200 may be implemented with a volatile memory device such as for example a dynamic random access memory (DRAM) and/or a static random access memory (SRAM) or a non-volatile memory device such as for example a read only memory (ROM), a mask ROM (MROM), a programmable ROM (PROM), an erasable programmable ROM (EPROM), an electrically erasable programmable ROM (EEPROM), a ferroelectric random access memory (FRAM), a phase change RAM (PRAM), a magnetoresistive RAM (MRAM), and/or a resistive RAM (RRAM).

The controller 100 may control storage of data in the memory device 200. For example, the controller 100 may control the memory device 200 in response to a request from the host device. The controller 100 may provide data read from the memory device 200 to the host device, and may store data provided from the host device into the memory device 200.

The controller 100 may include a storage 110, a control component 120, which may be implemented as a processor such as for example a central processing unit (CPU), an error correction code (ECC) component 130, a host interface (I/F) 140 and a memory interface (I/F) 150, which are coupled through a bus 160.

The storage 110 may serve as a working memory of the memory system 10 and the controller 100, and storage 110 may store data for driving the memory system 10 and the controller 100 The storage 110 may store data for encoding and/or decoding the data bit information being transmitted/received. For example, when the controller 100 controls operations of the memory device 200, the storage 110 may store data used by the controller 100 and the memory device 200 for such operations as read, write, program and erase operations, including encoding and decoding.

The storage 110 may be implemented with a volatile memory such as a static random access memory (SRAM) or a dynamic random access memory (DRAM). As described above, the storage 110 may store data used by the host device in the memory device 200 for the read and write operations. To store the data, the storage 110 may include a program memory, a data memory, a write buffer, a read buffer, a map buffer, and the like.

The control component 120 may control general operations of the memory system 10, and a write operation or a read operation for the memory device 200, in response to a write request or a read request from the host device. The control component 120 may drive firmware or other program instructions, which can be referred to as a flash translation layer (FTL), to control operations of the memory system 10. For example, the FTL may perform operations such as logical-to-physical (L2P) mapping, wear leveling, garbage collection, and/or bad block handling. The L2P mapping is known as logical block addressing (LBA).

The ECC component 130 may detect and correct errors in the data read from the memory device 200 during the read operation as detailed below. In one embodiment, the ECC component 130 may not correct error bits when the number of the error bits is greater than or equal to a threshold number of correctable error bits, but instead may output an error correction fail signal indicating failure in correcting the error bits.

In various embodiments, the ECC component 130 may perform an error correction operation based on a coded modulation such as for example a low density parity check (LDPC) code, a Bose-Chaudhuri-Hocquenghem (BCH) code, a turbo code, a turbo product code (TPC), a Reed-Solomon (RS) code, a convolution code, a recursive systematic code (RSC), a trellis-coded modulation (TCM), or a Block coded modulation (BCM). As such, the ECC component 130 may include any and all circuits, systems or devices suitable for error correction operation. In one embodiment of the present invention, a quasi-cyclic LDPC matrix (detailed below) is used for data recovery and bit error reporting.

The host interface 140 may communicate with the host device through one or more of various communication standards or interfaces such as for example a universal serial bus (USB), a multi-media card (MMC), a peripheral component interconnect express (PCI-β or PCIe), a small computer system interface (SCSI), a serial-attached SCSI (SAS), a serial advanced technology attachment (SATA), a parallel advanced technology attachment (PATA), an enhanced small disk interface (ESDI), and an integrated drive electronics (IDE).

The memory interface 150 may provide an interface between the controller 100 and the memory device 200 to allow the controller 100 to control the memory device 200 in response to a request from the host device. The memory interface 150 may generate control signals for the memory device 200 and process data under the control of the control component 120. In one embodiment where the memory device 200 is a flash memory such as a NAND flash memory, the memory interface 150 may generate control signals for the memory and process data under the control of the control component 120.

The memory device 200 as shown for example in FIG. 2 may include a memory cell array 210, a control circuit 220, a voltage generation circuit 230, a row decoder 240, a page buffer 250, which may be in the form of an array of page buffers, a column decoder 260, and an input and output (input/output) circuit 270. The memory cell array 210 may include a plurality of memory blocks 211 which may store data. The voltage generation circuit 230, the row decoder 240, the page buffer array 250, the column decoder 260 and the input/output circuit 270 may form a peripheral circuit for the memory cell array 210. The peripheral circuit may perform program, read, or erase operations of the memory cell array 210. The control circuit 220 may control the peripheral circuit.

The voltage generation circuit 230 may generate operational voltages of various levels. For example, in an erase operation, the voltage generation circuit 230 may generate operational voltages of various levels such as for example an erase voltage and a pass voltage.

The row decoder 240 may be in electrical communication with the voltage generation circuit 230, and the plurality of memory blocks 211. The row decoder 240 may select at least one memory block among the plurality of memory blocks 211 in response to a row address generated by the control circuit 220, and transmit operation voltages supplied from the voltage generation circuit 230 to the selected memory blocks.

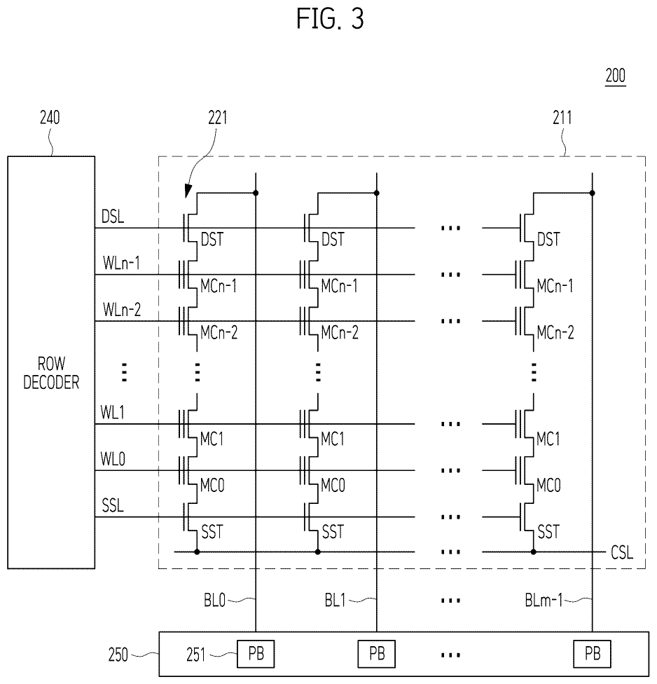

The page buffer 250 may be coupled with the memory cell array 210 through bit lines BL (shown in FIG. 3). The page buffer 250 may precharge the bit lines BL with a positive voltage, transmit data to, and receive data from, a selected memory block in program and read operations, or temporarily store transmitted data, in response to page buffer control signal(s) generated by the control circuit 220.

The column decoder 260 may transmit data to, and receive data from, the page buffer 250 or may transmit and receive data to and from the input/output circuit 270.

The input/output circuit 270 may transmit to the control circuit 220 a command and an address, received from an external device (e.g., the memory controller 100 of FIG. 1), transmit data from the external device to the column decoder 260, or output data from the column decoder 260 to the external device.

The control circuit 220 may control the peripheral circuit in response to the command and the address.

FIG. 3 is a circuit diagram illustrating a memory block of a semiconductor memory device in accordance with one embodiment of the present invention. For example, the memory block of FIG. 3 may be any of the memory blocks 211 of the memory cell array 210 shown in FIG. 2.

Referring to FIG. 3, the memory block 211 may include a plurality of word lines WL0 to WLn-1, a drain select line DSL and a source select line SSL coupled to the row decoder 240. These lines may be arranged in parallel, with the plurality of word lines between the DSL and SSL.

The memory block 211 may further include a plurality of cell strings 221 respectively coupled to bit lines BL0 to BLm-1. The cell string of each column may include one or more drain selection transistors DST and one or more source selection transistors SST. In the illustrated embodiment, each cell string has one DST and one SST. In a cell string, a plurality of memory cells or memory cell transistors MC0 to MCn-1 may be serially coupled between the selection transistors DST and SST. Each of the memory cells may be formed as a multiple level cell. For example, each of the memory cells may be formed as a single level cell (SLC) storing 1 bit of data. Each of the memory cells may be formed as a multi-level cell (MLC) storing 2 bits of data. Each of the memory cells may be formed as a triple-level cell (TLC) storing 3 bits of data. Each of the memory cells may be formed as a quadruple-level cell (QLC) storing 4 bits of data.

The source of the SST in each cell string may be coupled to a common source line CSL, and the drain of each DST may be coupled to the corresponding bit line. Gates of the SSTs in the cell strings may be coupled to the SSL, and gates of the DSTs in the cell strings may be coupled to the DSL. Gates of the memory cells across the cell strings may be coupled to respective word lines. That is, the gates of memory cells MC0 are coupled to corresponding word line WL0, the gates of memory cells MC1 are coupled to corresponding word line WL1, etc. The group of memory cells coupled to a particular word line may be referred to as a physical page. Therefore, the number of physical pages in the memory block 211 may correspond to the number of word lines.

The page buffer array 250 may include a plurality of page buffers 251 that are coupled to the bit lines BL0 to BLm-1. The page buffers 251 may operate in response to page buffer control signals. For example, the page buffers 251 my temporarily store data received through the bit lines BL0 to BLm-1 or sense voltages or currents of the bit lines during a read or verify operation.

In various embodiments of the present invention, the memory blocks 211 may include a NAND-type flash memory cell. However, the memory blocks 211 are not limited to such cell type, and may include NOR-type flash memory cell(s). Memory cell array 210 may be implemented as a hybrid flash memory in which two or more types of memory cells are combined, or one-NAND flash memory in which a controller is embedded inside a memory chip.

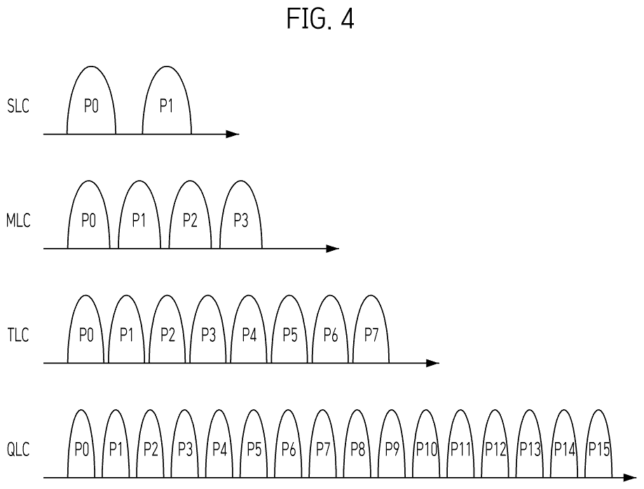

FIG. 4 is a diagram illustrating distributions of states or program voltage (PV) levels for different types of cells of a memory device.

Referring to FIG. 4, each of memory cells may be implemented with a specific type of cell, for example, a single level cell (SLC) storing 1 bit of data, a multi-level cell (MLC) storing 2 bits of data, a triple-level cell (TLC) storing 3 bits of data, or a quadruple-level cell (QLC) storing 4 bits of data. Usually, all memory cells in a particular memory device are of the same type, but that is not a requirement.

An SLC may include two states P0 and P1. P0 may indicate an erase state, and P1 may indicate a program state. Since the SLC can be set in one of two different states, each SLC may program or store 1 bit according to a set coding method. An MLC may include four states P0, P1, P2 and P3. Among these states, P0 may indicate an erase state, and P1 to P3 may indicate program states. Since the MLC can be set in one of four different states, each MLC may program or store two bits according to a set coding method. A TLC may include eight states P0 to P7. Among these states, P0 may indicate an erase state, and P1 to P7 may indicate program states. Since the TLC can be set in one of eight different states, each TLC may program or store three bits according to a set coding method. A QLC may include 16 states P0 to P15. Among these states, P0 may indicate an erase state, and P1 to P15 may indicate program states. Since the QLC can be set in one of sixteen different states, each QLC may program or store four bits according to a set coding method.

Referring back to FIGS. 2 and 3, the memory device 200 may include a plurality of memory cells (e.g., NAND flash memory cells). The memory cells are arranged in an array of rows and columns as shown in FIG. 3. The cells in each row are connected to a word line (e.g., WL0), while the cells in each column are coupled to a bit line (e.g., BL0). These word and bit lines are used for read and write operations. During a write operation, the data to be written (‘1’ or ‘0’) is provided at the bit line while the word line is addressed. During a read operation, the word line is again addressed, and the threshold voltage of each cell can then be acquired from the bit line. Multiple pages may share the memory cells that belong to (i.e., are coupled to) the same word line. When the memory cells are implemented with MLCs, the multiple pages include a most significant bit (MSB) page and a least significant bit (LSB) page. When the memory cells are implemented with TLCs, the multiple pages include an MSB page, a center significant bit (CSB) page and an LSB page. When the memory cells are implemented with QLCs, the multiple pages include an upper significant bit (USB) page, an MSB page, a CSB page and an LSB page. The memory cells may be programmed for example using a coding scheme (e.g., Gray coding) in order to increase the capacity of the memory system 10 such as SSD.

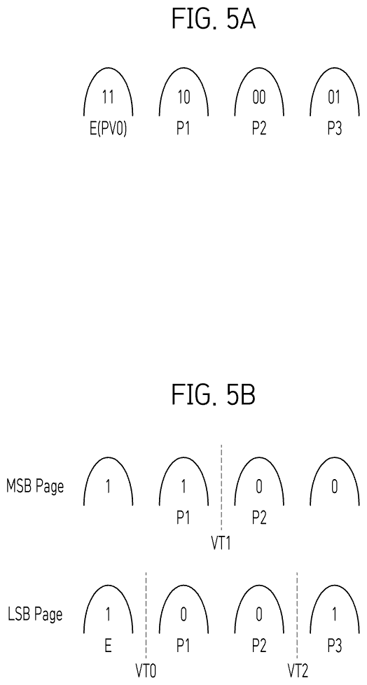

FIG. 5A is a diagram illustrating an example of coding for a multi-level cell (MLC).

Referring to FIG. 5A, an MLC may be programmed using a set type of coding. An MLC may have 4 program states, which include an erased state E (or PV0) and a first program state PV1 to a third program state PV3. The erased state E (or PV0) may correspond to “11.” The first program state PV1 may correspond to “10.” The second program state PV2 may correspond to “00.” The third program state PV3 may correspond to “01.”

In the MLC, as shown in FIG. 5B, there are 2 types of pages including LSB and MSB pages. 1 or 2 thresholds may be applied in order to retrieve data from the MLC. For an MSB page, the single threshold value is VT1. VT1 distinguishes between the first program state PV1 and the second program state PV2. For an LSB page, 2 thresholds include a threshold value VT0 and a threshold value VT2. VT0 distinguishes between the erased state E and the first program state PV1. VT2 distinguishes between the second program state PV2 and the third program state PV3.

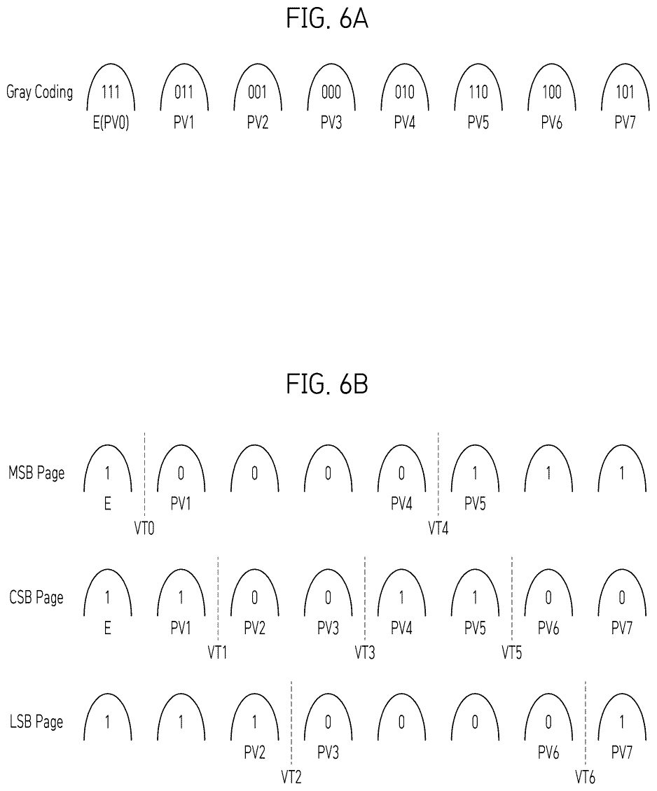

FIG. 6A is a diagram illustrating an example of Gray coding for a triple-level cell (TLC). FIG. 6B is a diagram illustrating state distributions for pages of a triple-level cell (TLC).

Referring to FIG. 6A, a TLC may be programmed using Gray coding. A TLC may have 8 program states, which include an erased state E (or PV0) and a first program state PV1 to a seventh program state PV7. The erased state E (or PV0) may correspond to “111.” The first program state PV1 may correspond to “011.” The second program state PV2 may correspond to “001.” The third program state PV3 may correspond to “000.” The fourth program state PV4 may correspond to “010.” The fifth program state PV5 may correspond to “110.” The sixth program state PV6 may correspond to “100.” The seventh program state PV7 may correspond to “101.”

In the TLC, as shown in FIG. 6B, there are 3 types of pages including LSB, CSB and MSB pages. 2 or 3 thresholds may be applied in order to retrieve data from the TLC. For an MSB page, 2 thresholds include a threshold value VT0 that distinguishes between an erased state E and a first program state PV1 and a threshold value VT4 that distinguishes between a fourth program state PV4 and a fifth program state PV5. For a CSB page, 3 thresholds include VT1, VT3 and VT5. VT1 distinguishes between a first program state PV1 and a second program state PV2. VT3 distinguishes between a third program state PV3 and the fourth program state PV4. VT5 distinguishes between the fourth program state PV5 and the sixth program state PV6. For an LSB page, 2 thresholds include VT2 and VT6. VT2 distinguishes between the second program state PV2 and the third program state PV3. VT6 distinguishes between the sixth program state PV6 and a seventh program state PV7.

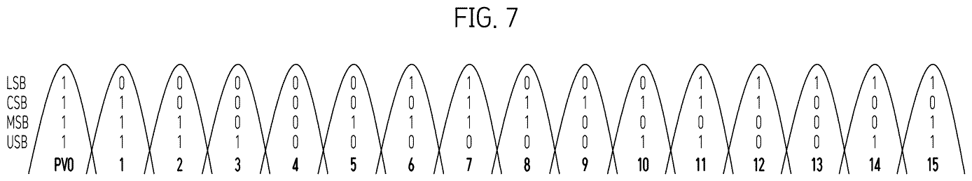

FIG. 7 is a diagram illustrating one example of Gray coding and state distributions for pages of a quadruple-level cell (QLC).

Referring to FIG. 7, a QLC may be programmed using Gray coding. A QLC may have 16 program states, which include an erased state PV0 (or E) and a first program state PV1 to a 15th program state PV15. The erased state PV0 may correspond to “1111.” The first program state PV1 may correspond to “0111.” The second program state PV2 may correspond to “0011.” The third program state PV3 may correspond to “0001.” The fourth program state PV4 may correspond to “0000.” The fifth program state PV5 may correspond to “0010.” The sixth program state PV6 may correspond to “1010.” The seventh program state PV7 may correspond to “1110.” The eighth program state PV8 may correspond to “0110.” The ninth program state PV9 may correspond to “0100.” The tenth program state PV10 may correspond to “0101.” The 11th program state PV11 may correspond to “1101.” The 12th program state PV12 may correspond to “1100.” The 13th program state PV13 may correspond to “1000.” The 14th program state PV14 may correspond to “1001.” The 15th program state PV15 may correspond to “1011.”

In the QLC, as shown in FIG. 7, there are 4 types of pages including LSB, CSB, MSB and USB pages. 3 or 4 thresholds may be applied in order to retrieve data from the QLC. For an USB page, 4 thresholds include a threshold value that distinguishes between a program state PV3 and a program state PV4, a threshold value that distinguishes between a program state PV9 and a program state PV10, a threshold value that distinguishes between a program state PV11 and a program state PV12, and a threshold value that distinguishes between a program state PV13 and a program state PV14. For an MSB page, 4 thresholds include a threshold value that distinguishes between a program state PV2 and a program state PV3, a threshold value that distinguishes between a program state PV4 and a program state PV5, a threshold value that distinguishes between a program state PV8 and a program state PV9, and a threshold value that distinguishes between a program state PV14 and a program state PV15. For a CSB page, 3 thresholds include a threshold value that distinguishes between a program state PV1 and a program state PV2, a threshold value that distinguishes between a program state PV6 and a program state PV7, and a threshold value that distinguishes between a program state PV12 and a program state PV13. For an LSB page, 4 thresholds include a threshold value that distinguishes between an erased state PV0 and a program state PV1, a threshold value that distinguishes between a program state PV5 and a program state PV6, a threshold value that distinguishes between a program state PV7 and a program state PV8, and a threshold value that distinguishes between a program state PV10 and a program state PV11.

After a memory array including a plurality of memory cells is programmed as described in FIGS. 5A, 6A and 7, when a read operation is performed on the memory array using a reference voltage such as a read threshold voltage (also called “read voltage level” or “read threshold”), the electrical charge levels of the memory cells (e.g., threshold voltage levels of transistors of memory cells) are compared to one or more reference voltages to determine the state of individual memory cells. When a specific read threshold is applied to the memory array, those memory cells that have threshold voltage levels higher than the reference voltage are turned on and detected as “on” cell, whereas those memory cells that have threshold voltage levels lower than the reference voltage are turned off and detected as “off” cell, for example. Therefore, each read threshold is arranged between neighboring threshold voltage distribution windows corresponding to different programmed states so that each read threshold can distinguish such programmed states by turning on or off the memory cell transistors.

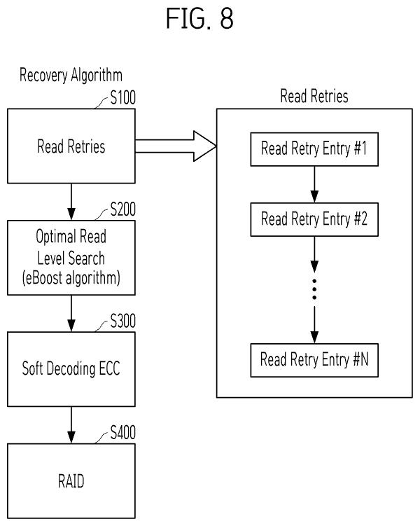

When a read operation is performed on memory cells in a data storage device, the threshold voltage levels of the memory cells are compared to more than one read threshold level to determine the state of individual memory cells. Read errors can be caused by distorted or overlapped threshold voltage distributions. An ideal memory cell threshold voltage distribution can be significantly distorted or overlapped due to, e.g., program and erase (P/E) cycles, cell-to-cell interference, and/or data retention errors. For example, as program/erase cycles increase, the margin between neighboring threshold voltage distributions of different programmed states decreases and eventually the distributions overlap. As a result, the memory cells with threshold voltages that fall within the overlapping region of the neighboring distributions may be read as being programmed to a value other than the original targeted value and thus cause read errors. Such read errors may be managed in many situations by using error correction codes (ECC). When the number of bit errors on a read operation exceeds the ECC correction capability of the data storage, the read operation using a set read threshold voltage fails. The set read threshold voltage may be a previously used read threshold voltage (i.e., a historical read threshold voltage). The historical read threshold voltage may be the read threshold voltage used in the last successful decoding, that is, a read voltage used in a read-passed read operation performed before read retry operations. When the read operation using the set read threshold voltage failed, the controller 120 may control an error recovery algorithm such as for example the algorithm shown in FIG. 8.

Referring to FIG. 8, a controller (such as control component 120 in FIG. 2) may perform one or more read retry operations for the memory cells using one or more read threshold voltages applied in a set order (S100). For example, the read threshold voltages may include N (e.g., N is 5 or 10) read threshold voltages (or read voltage levels) including a first read threshold voltage to an Nth read threshold voltage. The first read threshold voltage may be a previously used read threshold voltage (i.e., a history (historical) read threshold voltage). The historical read threshold voltage may be the read threshold voltage used in the last successful decoding, that is, a read voltage used in a read-passed read operation performed before the read retry operations. The controller 120 may perform the read retry operations until it is determined that decoding associated with a corresponding read retry operation is successful.

When all read retry operations using the read threshold voltages have failed, the controller 120 may perform additional recovery operations. For example, the additional recovery operations may include an optimal read threshold voltage search (S200), a soft decoding using an error correction code (ECC) (S300) and/or a redundant array of independent disks (RAID) recovery (S400).

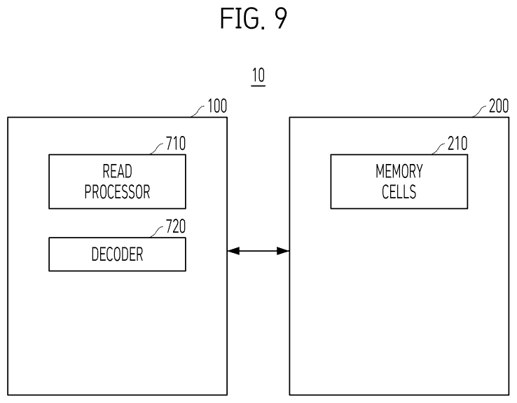

FIG. 9 is a diagram illustrating a memory system 10 in accordance with one embodiment of the present invention.

Referring to FIG. 9, the memory system 10 may include a controller 100 and a memory device 200. The memory device 200 may include a plurality of memory cells (e.g., NAND flash memory cells) 210. The memory cells are arranged in an array of rows and columns such as shown in FIG. 3. The cells in each row are connected to a word line (e.g., WL0), while the cells in each column are coupled to a bit line (e.g., BL0). These word and bit lines are used for read and write operations. During a write operation, the data to be written (‘1’ or ‘0’) is provided at the bit line while the word line is addressed. During a read operation, the word line is again addressed, and the threshold voltage of each cell can then be acquired from the bit line. Multiple pages may share the memory cells that belong to (i.e., are coupled to) the same word line. When the memory cells are implemented with MLCs, the multiple pages include a most significant bit (MSB) page and a least significant bit (LSB) page. When the memory cells are implemented with TLCs, the multiple pages include an MSB page, a center significant bit (CSB) page and an LSB page. When the memory cells are implemented with QLCs, the multiple pages include an USB page, an MSB page, a CSB page and an LSB page. The memory cells may be programmed using a coding scheme (e.g., Gray coding) in order to increase the capacity of the memory system 10 such as an SSD.

The controller 100 may include a read processor 710, and a decoder 720. Although it is illustrated that components of the controller 100 are implemented separately, these components may be implemented with an internal component (i.e., firmware (FW)) of the control component 120 in FIG. 2. The controller 100 and the memory device 200 may include various other components such as those shown in FIG. 2. Further, the controller 100 may include a media management processor 730 which is described later.

The read processor 710 may control one or more read operations for the memory device 200 in response to a read request from a host (e.g., the host 5 of FIG. 1). The read processor 710 may control the read operations using various read thresholds. The decoder 720 may decode data associated with the read operations.

In various embodiments of the present invention, the read processor 710 may control a read operation for the memory cells using a select read threshold from a set read level table. In various embodiments, the read level table may include multiple read thresholds and the select read threshold may include a default read threshold as described with reference to FIGS. 5B, 6B and 7.

In one embodiment of the present invention, it is determined whether the read operation using a read threshold selected from a read threshold set succeeded or failed, depending on the decoding result of the decoder 720. When the read operation using the selected read threshold failed, the read processor 710 may control one or more read retry operations for the memory cells using read retry entries.

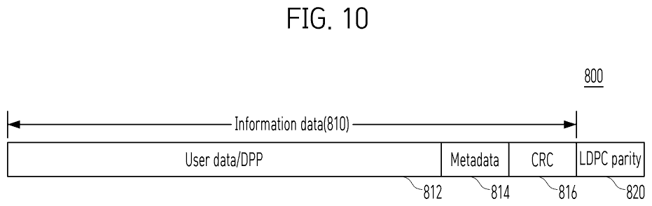

As background, FIG. 10 is a diagram illustrating a format of a codeword 800 to be stored in a storage system. Referring to FIG. 8, the codeword 800 may include information data 810 (information bits or user data) and LDPC parity data 820. In some embodiments, the codeword 800 may be generated by the LDPC codes noted above.

The information data 810 may include user data with data path protection (DPP) 812, meta-data 814 and cyclic redundancy check (CRC) parity bits 816. A CRC code which is an error-detecting code commonly used in digital networks and storage devices may detect accidental changes to raw data.

In a typical LDPC decoder, if the LDPC checksum is zero, the decoding may be terminated. The CRC parity bits 816 will be computed based on the decoded user data 812 and meta-data 814 after the LDPC decoding. If the computed CRC parity bits match the decoded CRC parity bits, decoding may be successful. Otherwise, a mis-correction may be declared.

As more background, compared to TLC, QLC NAND provides lower cost and higher density with smaller form factor and power consumption and quickly became popular in NAND flash and SSD markets. As a QLC NAND has higher raw bit error rates (rBERs) than TLC NAND, the quality-of-service (QoS) (i.e., the latency distribution) and the reliability may be degraded. Accordingly, products using QLC NAND are needed to maintain similar QoS and reliability comparing to TLC based products. Embodiments of the present invention provide schemes to improve QoS and reliability for QLC based systems (e.g., SSDs) with minimal overhead and cost to system-on-chip (SoC) and firmware (FW).

Correction Capability of Soft Decode without Additional Reads

In a typical ECC solution, soft decoding typically has a higher correction capability (e.g., close to 2× correction capability) than hard decoding. Thus, utilizing soft decoding at an earlier stage of a read process may provide excellent correction capability in QLC applications. However, soft decoding requires multiple additional reads to the same page of a memory device (i.e., a NAND page) and causes longer latency than hard decoding. Accordingly, embodiments of the present invention provide a progressive read and soft decoding scheme capable of providing similar correction capability as soft decoding without additional reads.

### Quicker and More Accurate Center Vt Search

In a typical memory system (e.g., a SSD), before soft reads are performed, a few reads are used to find an optimal central sensing bias (i.e., an optimal read threshold voltage (Vt)) in each valley of a PV distribution. To get an accurate estimation of the optimal central sensing bias, many reads (for example, up to 20) can be performed with different read thresholds on the same page. Still, in some situations, the estimated sensing bias can still be away from the optimal read threshold voltage. A progressive read and soft decoding scheme (such as described below) can reduce the number of search reads and improve the accuracy of the estimated central sensing bias of each valley.

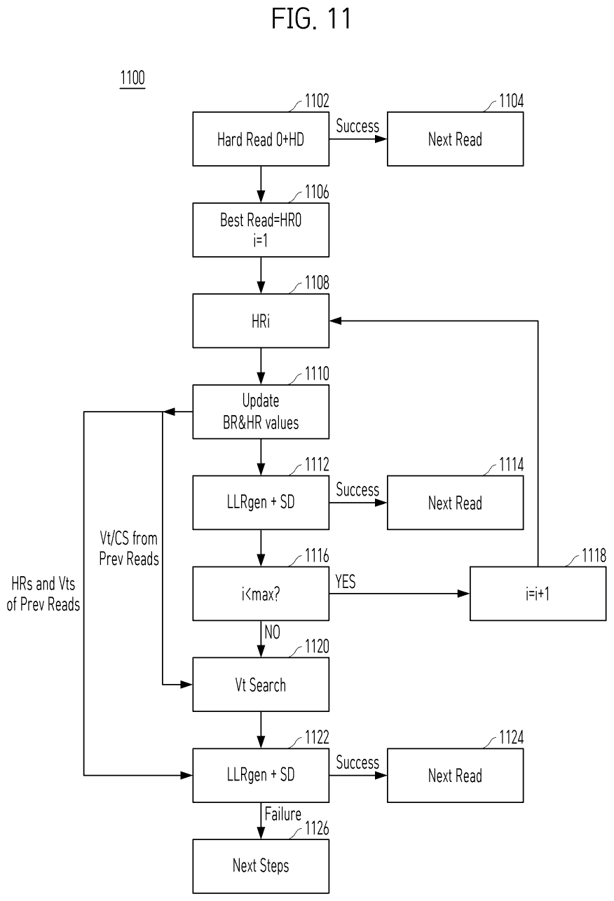

FIG. 11 illustrates a progressive read and decoding operation method 1100 in accordance with embodiments of the present invention. The method 1100 may be performed by a memory system (e.g., the memory system 10 of FIG. 1), which includes a controller (e.g., the controller 100 of FIGS. 1 and 9) and a memory device (e.g., the memory device 200 of FIGS. 1 and 9) including one or more pages for storing data. The method 1100 performed by the controller may be implemented with firmware (FW), e.g., the firmware of the control component 120 of the controller 100 in FIG. 2, or the read processor 710 and the decoder 720 of the controller 100 in FIG. 9.

Referring to FIG. 11, when a read command is received from an external device (e.g., a host 5 of FIG. 1), a controller may perform first hard read (HR0) using a sensing bias (or a read bias) on a region (e.g., a page or cells) of a memory device and hard decoding (HD) (1102). When it is determined that the hard decoding succeeded, the controller may process a next read command (1104).

When it is determined that the hard decoding failed, the controller may determine a checksum of the first hard read, may record (store) the sensing bias and a hard read value for the first hard read (HR0) as a best read (1106), and proceed to a second hard read (1108). The second hard read may use a bias different from the sensing bias for the first hard read.

After the second hard read, the controller may determine a checksum of the second hard read and compare the checksum of the second hard read with a checksum of the first hard read (1110). Further, the controller may record the hard read with the smaller checksum as the best read. The sensing bias used for the best read and the hard read value obtained may be updated by the controller.

The controller may generate a log likelihood ratio (LLR) value based on the first and second hard read values (1112). In one embodiment, any bit that has inconsistent values from the first and second hard reads may be assigned to a weak LLR value (small magnitude). The bits with consistent values from the first and second hard reads may be assigned to a strong LLR value (large magnitude). The sign of LLR value follows the sign of the best read (BR) hard values (i.e., negative (−) for a bit 1 and positive (+) for a bit 0). The same logic can be extended to more reads. The strong and weak LLR values may depend on the precision of the LLR generation and decoding and can be optimized by maximizing decoder's correction capability. Here, “consistent” means that the first hard read value is the same as the second hard read value. For example, if the first read returns 1 and second read returns 1, it can be said that the first and second reads are consistent. One example is shown in the following list.

### List:

Assume LLR value range is [−3, +3], 1 may used for weak LLR
magnitude and 3 may be used for strong LLR magnitude.
First read values: [1, 0, 1, . . . , . . . , 0, 1]
First read CS: 1000
Second read values: [1, 1, 0, . . . , . . . , 1, 1]
Second read CS: 1200

Referring to the List, the first read is the best read due to smaller CS. The LLR sign follows the first read. The generated LLR values become: LLR values: [−3, +1, −1, . . . , . . . , +1, −3]. In the above example of the List, if an LLR value range is changed to be [−7, +7], 3 may be used for weak LLR magnitude and 7 may be used for strong LLR magnitude. Thus, the LLR values may become: LLR values: [−7, +3, −3, . . . , . . . , +3, −7].

Another way to generate LLR is to further consider the checksum of each of the previous hard reads. A high checksum may indicate that a bias is far away from an optimal read threshold voltage (Vt). A bias with a low checksum may be closer to the optimal Vt. Therefore, for any cell which has the same (i.e., consistent) read value for all the previous hard reads, if all the previous hard reads have a high CS (e.g., above 2000), the cell may be assigned with a relatively large LLR magnitude (e.g., 7 as the LLR magnitude). If all the previous hard reads have a low CS (e.g., below 1200), the cell may be assigned with a relatively small LLR magnitude (e.g., 5 as the LLR magnitude).

After LLR is generated, the controller may perform soft decoding (SD) (1112). When it is determined that the soft decoding succeeded, the controller may process a next read command (1114). When it is determined that the soft decoding failed, the controller may repeat the process above (1110, 1112) until a maximum number of attempts is reached (1116, 1118). During a third hard read and more, the LLR generation can follow similar scheme described above and may require more precision of LLR and decoder bit-width. The choice of a read bias for different hard reads can be designed separately. That is, this design means to optimize the read biases of each read retry entry such that the progressive soft decoding scheme of the present disclosure can have a better correction since the soft correction capability depends on the hard read biases.

When the number of hard reads reaches the maximum number of attempts (1116, NO), the controller may perform a search for the central Vt (potential optimal Vt) of each valley (1120). Vts and checksums discovered by previous failed hard reads can provide useful information about the optimal Vt. This can help narrow down the search range of the Vt search algorithm and reduce the number of search reads and also improve the accuracy of the Vt search algorithm.

After the Vt search, the controller may perform additional soft reads around the central Vt of each valley and generate the LLR for a soft decode (1122). When it is determined that the soft decoding succeeded, the controller may process a next read command (1124). When it is determined that the soft decoding failed, the controller may perform next steps (1126). In some embodiments, the next steps may include soft decoding with different sets of LLR table, or Chipkill (XOR) based data recovery. During LLR generation, the hard read values and Vts used in previous hard reads can provide more resolution to the LLR generation algorithm and further improve the correction capability. But this process comes with a cost of saving the hard read values of previous reads and additional precision of LLR and decoder bit-width.

### Early Termination

In some embodiments, the controller may compare the checksum (CS) of the best read with a pre-determined threshold. When it is determined that the checksum (CS) of the best read is greater than the pre-determined threshold (e.g., a), the controller may skip the LLR generation and SD operation (1112), and directly go to the Vt search operation (1120).

This early termination can save the latency for the case where all the previous history reads are very biased (i.e., having large CS). For example, when the CS of a read is greater than 2000, it can be said that the read is very biased. The threshold a can be optimized offline according to the correction capability of the LLRgen+SD operation at 1112.

### Ones Count of the Minimum CS Best Read

During the LLR generation, the controller may determine whether ones count of the best read is too high or too low. For example, the controller may determine |(the ones count-n/2)/(n/2)|>5%, where n is the codeword length. When it is determined that ones count of the best read is too high or too low, the controller can bias the corresponding LLR magnitudes for bit 1 and bit 0. The asymmetric LLR can further improve the correction capability.

In one embodiment, if ones count of the min checksum (CS) best read (i.e., the best read with the minimum CS) is very high, the controller may decrease the magnitude of negative LLR (bit 1) and increase the magnitude of positive LLR (bit 0). The metric “very high” is the same as “too high” noted above. “very high” means (the ones count-n/2)/(n/2)>5%, where n is the codeword length. If ones count of the min CS best read is very low, the controller may increase the magnitude of negative LLR (bit 1) and decrease the magnitude of positive LLR (bit 0). The metric “very low” is the same as “too low” noted above. “very low” means (n/2−the ones count)/(n/2)>5%, where n is the codeword length. For example, assume that the original generated LLR sequence is: [3, 2, −2, −3, . . . , . . . , 4, −4]. If ones count of the min CS best read is very high, the controller can decrease the magnitude of negative LLR by one and increase the magnitude of positive LLR by one. Thus, the final adjusted LLR will become [4, 3, −1, −2, . . . , . . . , 5, −3].

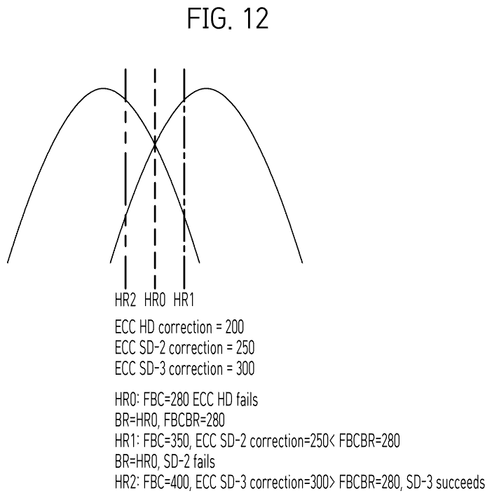

FIG. 12 is a diagram illustrating performance of a progressive read and decoding operation in accordance with embodiments of the present invention.

Referring to FIG. 12, an example in QLC applications is shown. This example focuses on the optimization of the read biases of a first read and subsequent read-retry entries, in QLC applications. Assume that ECC hard decoding (HD) has a correction capability of 200 bits, that 2-read soft decoding (SD-2) has a correction capability of 250 bits, and that 3-read soft decoding (SD-3) has correction capability of 300 bits.

As illustrated in FIG. 12, the first read HR0 (already at the optimal Vt) produces a FBC=280. Hard decoding fails because the ECC HD capability of 200 is less than the FBC=280.

The second read HR1 produces FBC=350 and the third read HR2 produces FBC=400. Neither read can be decoded by a hard decoder. In this case, a full Vt search and a soft read can be performed to recover data, but a full Vt search and a soft read take a very long latency. As a comparison, the proposed scheme at the third read will be sufficient to decode the noisy codeword because SD-3 correction capability is greater than FBC of best read (BR=HR0) (i.e., SD-3=300>FBCBR=280), illustrating the advantage of this scheme. In this case, optimization to the read biases of the first read or read retry (i.e., second and third reads) is not helpful because these reads will all fail hard decoding. Although a Vt search and a soft read and decoding can successfully decode the codeword, this takes significantly longer latency than the progressive read and decoding operation described above.

### Computerized Method

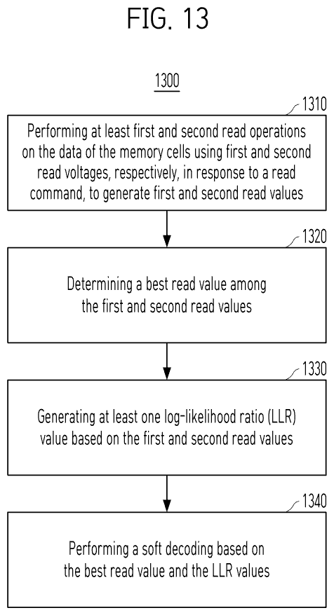

In one embodiment of the present invention, there is provided a method 1300 in FIG. 13 for performing media management operation according to one embodiment of the invention. The method 1300 may be performed by a memory system (e.g., the memory system 10 of FIG. 1), which includes a controller (e.g., the memory controller 100 of FIGS. 1 and 9) and a memory device (e.g., the semiconductor memory device 200 of FIGS. 1 and 9) including one or more pages (cells) for storing data. The method 1300 performed by the controller may be implemented with firmware (FW), e.g., the firmware of the control component 120 of the controller 100 in FIG. 2, or the read processor 710 and the decoder 720 of the controller 100 in FIG. 9.

Referring to FIG. 13, the method 1300 includes, at 1310, performing at least first and second read operations on the data of the memory cells using first and second read voltages, respectively, in response to a read command, to generate first and second read values.

The operation 1320 includes determining a best read value among the first and second read values. The operation 1330 includes generating at least one log-likelihood ratio (LLR) value based on the first and second read values. The operation 1340 includes performing a soft decoding based on the best read value and the LLR values.

In some embodiments, the performing of the at least first and second read operations includes: performing the first hard read operation, performing a first hard decoding on the first hard read value, and when it is determined that the first hard decoding failed, performing the second hard read operation to output the second hard read value.

In some embodiments, the determining of the best read value includes determining, as the best read value, one read value with a least checksum value, among the first and second read values.

In some embodiments, each of the first and second read values includes multiple bits, and the at least one LLR value is generated based on whether corresponding bits of the first read value and the second read value are consistent. Here, “consistent” means the first hard read value is the same as the second hard read value. For example, if the first read returns 1 and second read returns 1, it can be said that the first and second hard read values are consistent. Another example, if the first read returns 0 and second read returns 0, it can be said that the first and second hard read values are consistent.

In some embodiments, each of the first and second read values includes multiple bits, and the at least one LLR value is generated based on checksums on bits of the first read value and the second read value.

In some embodiments, the method 1300 further comprises determining whether the soft decoding succeeds.

In some embodiments, the method 1300 further comprises: when it is determined that the soft decoding failed, performing at least one additional read operation; and performing the determining, the generating and the performing of the soft decoding.

In some embodiments, the method 1300 further comprises: when the soft decoding failed a set number of times, searching for an optimal central voltage threshold (Vt) of each valley of a program voltage (PV) distribution.

In some embodiments, the method 1300 further comprises: when it is determined that a checksum of the best read is greater than a threshold value, skipping the determining of the best read value, the generating of the at least one LLR value and the performing of the soft decoding, and performing the search for the optimal central voltage threshold.

In some embodiments, the method 1300 further comprises: performing the determining of the best read value, the generating of the at least one LLR value and the performing of the soft decoding based on the optimal central voltage threshold.

Accordingly, embodiments of the present invention provide a scheme for providing progressive read and soft decoding operations. The progressive read and soft decoding scheme can reduce the number of search reads and improve the accuracy of the estimated central sensing bias of each valley.

Although the foregoing embodiments have been described in some detail for purposes of clarity of understanding, the invention is not limited to the details provided. There are many alternative ways of implementing the invention. The disclosed embodiments are illustrative and not restrictive. The present invention is intended to embrace all modifications and alternatives of the disclosed embodiments. Furthermore, the disclosed embodiments may be combined to form additional embodiments.

Indeed, implementations of the subject matter and the functional operations described in this patent document can be implemented in various systems, digital electronic circuitry, or in computer software, firmware, or hardware, including the structures disclosed in this specification and their structural equivalents, or in combinations of one or more of them. Implementations of the subject matter described in this specification can be implemented as one or more computer program products, i.e., one or more modules of computer program instructions encoded on a tangible and non-transitory computer readable medium for execution by, or to control the operation of, data processing apparatus. The computer readable medium can be a machine-readable storage device, a machine-readable storage substrate, a memory device, a composition of matter effecting a machine-readable propagated signal, or a combination of one or more of them. The term “data processing unit” or “data processing apparatus” encompasses all apparatus, devices, and machines for processing data, including by way of example a programmable processor, a computer, or multiple processors or computers. The apparatus can include, in addition to hardware, code that creates an execution environment for the computer program in question, e.g., code that constitutes processor firmware, a protocol stack, a database management system, an operating system, or a combination of one or more of them.

A computer program (also known as a program, software, software application, script, or code) can be written in any form of programming language, including compiled or interpreted languages, and it can be deployed in any form, including as a stand-alone program or as a module, component, subroutine, or other unit suitable for use in a computing environment. A computer program does not necessarily correspond to a file in a file system. A program can be stored in a portion of a file that holds other programs or data (e.g., one or more scripts stored in a markup language document), in a single file dedicated to the program in question, or in multiple coordinated files (e.g., files that store one or more modules, sub programs, or portions of code). A computer program can be deployed to be executed on one computer or on multiple computers that are located at one site or distributed across multiple sites and interconnected by a communication network.

The processes and logic flows described in this specification can be performed by one or more programmable processors executing one or more computer programs to perform functions by operating on input data and generating output. The processes and logic flows can also be performed by, and apparatus can also be implemented as, special purpose logic circuitry, e.g., an FPGA (field programmable gate array) or an ASIC (application specific integrated circuit).

Processors suitable for the execution of a computer program include, by way of example, both general and special purpose microprocessors, and any one or more processors of any kind of digital computer. Generally, a processor will receive instructions and data from a read only memory or a random access memory or both. The elements of a computer are a processor for performing instructions and one or more memory devices for storing instructions and data. Generally, a computer will also include, or be operatively coupled to receive data from or transfer data to, or both, one or more mass storage devices for storing data, e.g., magnetic, magneto optical disks, or optical disks. However, a computer need not have such devices. Computer readable media suitable for storing computer program instructions and data include all forms of non-volatile memory, media and memory devices, including by way of example semiconductor memory devices, e.g., EPROM, EEPROM, and flash memory devices. The processor and the memory can be supplemented by, or incorporated in, special purpose logic circuitry.

While this patent document contains many specifics, these should not be construed as limitations on the scope of any invention or of what may be claimed, but rather as descriptions of features that may be specific to particular embodiments of particular inventions. Certain features that are described in this patent document in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations, one or more features from a combination can in some cases be excised from the combination, and the combination may be directed to a sub-combination or variation of a sub-combination.

Similarly, while operations are depicted in the drawings in a particular order, this should not be understood as requiring that such operations be performed in the particular order shown or in sequential order, or that all illustrated operations be performed, to achieve desirable results. Moreover, the separation of various system components in the embodiments described in this patent document should not be understood as requiring such separation in all embodiments.

Only a few implementations and examples are described and other implementations, enhancements and variations can be made based on what is described and illustrated in this patent document.

What is claimed is:

1. A memory system comprising:
a memory device including one or more memory cells for storing data; and
a controller coupled to the memory device and configured to:
perform at least first and second read operations on the data of the memory cells using first and second read voltages, respectively, in response to a read command, to generate first and second read values;
determine a best read value among the first and second read values;
generate at least one log-likelihood ratio (LLR) value based on the first and second read values; and
perform a soft decoding based on the best read value and the LLR values.

2. The memory system of claim 1, wherein the controller
performs the first hard read operation,
performs a first hard decoding on the first hard read value, and
when it is determined that the first hard decoding failed, performs the second hard read operation to output the second hard read value.

3. The memory system of claim 1, wherein the controller determines, as the best read value, one read value with a least checksum value, among the first and second read values.

4. The memory system of claim 1, wherein each of the first and second read values includes multiple bits, and
the controller generates the at least one LLR value based on whether corresponding bits of the first read value and the second read value are consistent.

5. The memory system of claim 1, wherein each of the first and second read values includes multiple bits, and
the controller generates the at least one LLR value based on checksums on bits of the first read value and the second read value.

6. The memory system of claim 1, wherein the controller is further configured to determine whether the soft decoding succeeds.

7. The memory system of claim 1, wherein, when it is determined that the soft decoding failed, the controller is further configured to:
perform at least one additional read operation;
determine the best read value;
generate the at least one LLR value; and
perform the soft decoding.

8. The memory system of claim 7, wherein, when the soft decoding failed a set number of times,
the controller is further configured to search for an optimal central voltage threshold (Vt) of each valley of a program voltage (PV) distribution.

9. The memory system of claim 8, wherein the controller is further configured to:
when it is determined that a checksum of the best read is greater than a threshold value, perform the search for the optimal central voltage threshold.

10. The memory system of claim 8, wherein the controller is further configured to determine the best read value, generate the at least one LLR value, and perform the soft decoding, based on the optimal central voltage threshold.

11. A method for operating a memory system including a memory device including one or more memory cells for storing data, and a controller coupled to the memory device, comprising:
performing at least first and second read operations on the data of the memory cells using first and second read voltages, respectively, in response to a read command, to generate first and second read values;
determining a best read value among the first and second read values;
generating at least one log-likelihood ratio (LLR) value based on the first and second read values; and
performing a soft decoding based on the best read value and the LLR values.

12. The method of claim 11, wherein the performing of the at least first and second read operations includes:
performing the first hard read operation,
performing a first hard decoding on the first hard read value, and
when it is determined that the first hard decoding failed, performing the second hard read operation to output the second hard read value.

13. The method of claim 11, wherein the determining of the best read value includes determining, as the best read value, one read value with a least checksum value, among the first and second read values.

14. The method of claim 11, wherein each of the first and second read values includes multiple bits, and
the at least one LLR value is generated based on whether corresponding bits of the first read value and the second read value are consistent.

15. The method of claim 11, wherein each of the first and second read values includes multiple bits, and
the at least one LLR value is generated based on checksums on bits of the first read value and the second read value.

16. The method of claim 11, further comprising determining whether the soft decoding succeeds.

17. The method of claim 11, further comprising:
when it is determined that the soft decoding failed,
performing at least one additional read operation;
determining the best read value;
generating the at least one LLR value; and
performing the soft decoding.

18. The method of claim 17, further comprising:
when the soft decoding failed a set number of times,
searching for an optimal central voltage threshold (Vt) of each valley of a program voltage (PV) distribution.

19. The method of claim 18, further comprising:
when it is determined that a checksum of the best read is greater than a threshold value,
performing the search for the optimal central voltage threshold.

20. The method of claim 18, further comprising:
determining the best read value, generating the at least one LLR value, and performing the soft decoding, based on the optimal central voltage threshold.
